(19) United States
(12) Patent Application Publication
(10) Pub. No.: US 2023/0299552 A1
(43) Pub. Date: Sep. 21, 2023

(54) SELF-MODULATING POWER LASER CONTROL SYSTEM AND METHOD

(71) Applicant: SWIROC CORP., Hsinchu City (TW)

(72) Inventors: Kai-Hsiu LIAO, Hsinchu City (TW); Su-Hung HUANG, Hsinchu City (TW); Yi-Jing YOU, Hsinchu City (TW)

(21) Appl. No.: 17/696,260

(22) Filed: Mar. 16, 2022

(51) Int. Cl. H01S 3/102

(52) U.S. Cl. CPC H01S 3/102

(57) ABSTRACT

The invention provides a self-modulating input electrical power laser control system and method. After the laser is turned on for a period of time, the control module reduces the initial electrical power to the operating power of the laser, and it maintains the operating power until the laser is turned off, which can reduce the extra power consumption and achieve the energy-efficiency.

### BACKGROUND OF THE INVENTION

### 1. Field of the Invention

The present invention relates to the field of lasers, particularly a laser control system and method capable of adjusting the electric power of the laser.

### 2. Description of the Prior Art

High-power laser is important to the material processing applications. Especially, the fiber laser has become the mainstream due to their high conversion efficiency and small size. It requires voltage overhead to initiate the laser system with high optical power output. The electrical power is corresponding to the applied voltage, i.e. the startup voltage is higher than the operating voltage.

In conventional laser system, the operating voltage is set at a constant value with maximum output voltage, as shown in FIG. 1. However, the voltage overhead becomes unnecessary after laser activation. The extra power (voltage overhead) is converted to heat and dissipated. Moreover, the dissipated heat may impact the reliability or reduce the lifetime of the laser system.

### SUMMARY OF THE INVENTION

In view of the above energy consumption problem, the present invention provides a laser control system for self-modulating electrical power. After a startup period to activate the laser, the applied voltage is decreased to reduce the dissipated power.

A laser control system with self-modulating power, comprising:
a control module; and
a laser light source module connected to the control module for modulating laser power;
when the laser light source module outputs the laser light with an initial power for a period of time, the control module controls the laser light source module to reduce the initial power to the operation power and maintains the output of the laser light with the operation power.

A laser control method for self-modulating power, comprising:
controlling a laser light source module to output a laser light with an initial power through a control module; and
when the laser light source module outputs the laser light with the initial power for a period of time, the control module controls the laser light source module to reduce the initial power to an operating power and maintain the output of the laser light with the operation power.

### BRIEF DESCRIPTION OF THE DRAWINGS

FIG. 1 is a schematic diagram of general laser operating with a constant voltage.

FIG. 2 is a schematic block diagram of the laser control system of the present invention.

FIG. 3 is a schematic diagram of modulating laser operating voltage of the present invention.

FIG. 4 is a graph showing the control voltage and power consumption with or without modulating the laser voltage.

FIG. 5 is a flowchart of the laser control method of the present invention.

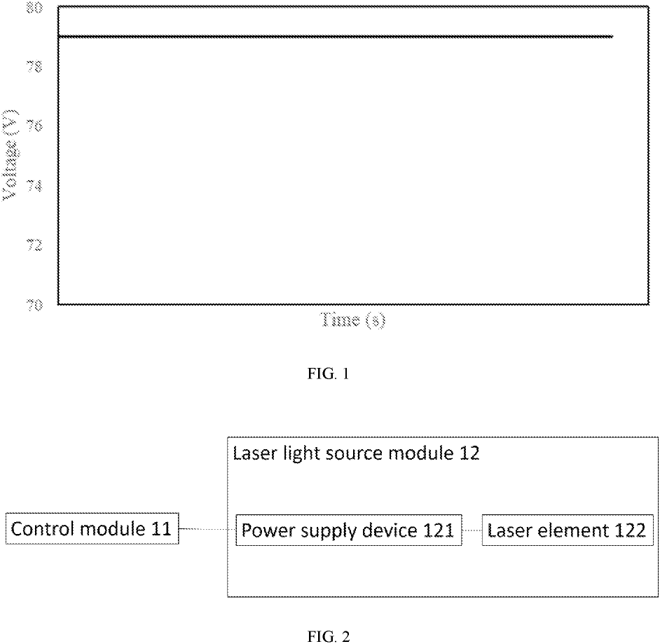

### DESCRIPTION OF THE PREFERRED EMBODIMENTS

Below embodiments accompanied with drawings are used to explain the spirit of this invention to have better understanding for the person in this art, not used to limit the scope of this invention, which is defined by the claims. The applicant emphasizes the element quantity and size are schematic only. Moreover, some parts might be omitted to skeletally represent this invention for conciseness.

The laser control system of the present invention provides an initial voltage (or a startup voltage) and a stable voltage (or an operating voltage) to the laser element. The initial voltage is used to activate the laser element during the initial period and the stable voltage is used to stabilize the laser element after the initial period.

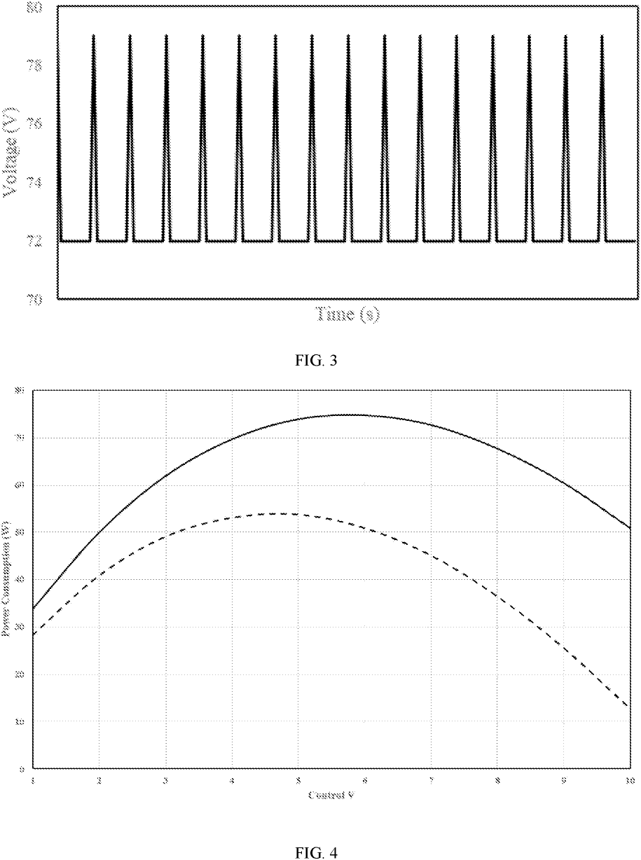

Refer to FIG. 2, which is a block diagram of the laser control system of the present invention. The laser control system comprises a control module 11 and a laser light source module 12, wherein the laser light source module 12 comprises a laser element 122 and a power supply device 121, and the power supply device 121 is connected between the control module 11 and the laser element 122. The control module 11 outputs an activation signal to the power supply device 121 to provide an initial voltage to initiate the laser element 122 to emit the laser light. In this embodiment, the initial voltage is 70-80 V.

The laser light is activated for a period, such as 10-30 µs, preferably 20-30 µs, and the control module 11 outputs a regulation signal to the power supply device 121 to change the initial voltage into the operating voltage. In general, the operation voltage is lower than the initial voltage for 5~10 V, which depends on the laser type. The operation voltage maintains the laser element 122 to output the laser light. The initial power (corresponding to the initial voltage) is used to activate the laser element 122 and the operating power (corresponding to the operating voltage) is used to maintain the laser element 122 outputs the laser light emission. It is obvious that the operating power is lower than the initial power. In other embodiments, the laser will be turned on/off several times in the actual manufacturing process, and the schematic diagram of the modulating voltage is shown in FIG. 3. The control module 11 gives an initial voltage of 79 V, and after 20 µs, the control module 11 reduces the voltage to 72 V, wherein the voltage difference is 7 V as the voltage overhead.

FIG. 4 is a comparison diagram of the power consumption of the conventional laser processing (solid line) and the self-modulating power laser processing of the present invention (dotted line). Under different control voltages, reducing the operating voltage can significantly reduce the power consumption by 5~50 W.

In one embodiment, the laser element 122 of the laser light source module 12 may be a semiconductor laser, a fiber laser, a carbon dioxide laser, a solid-state laser, a liquid laser, a gas laser, a YAG laser, or other devices that can generate high-power laser light, and laser light include laser light in various wavelength bands, such as infrared light, blue light, or green light, etc.

In one embodiment, the control module 11 includes an operation interface (not shown) for the user to input the required laser parameters, and the laser parameters of different types of panels can also be preset and stored in the memory of the control module 11. The user can start the laser only by selecting the desired setting package, which can improve efficiency, reduce human error and maintain a certain quality.

In one embodiment, the laser light source module 12 further includes a laser head element (not shown) disposed on the laser element 122 as a light outlet for the laser light, and the laser head element outputs the laser light, wherein the laser head element can adjust the diameter of the laser beam.

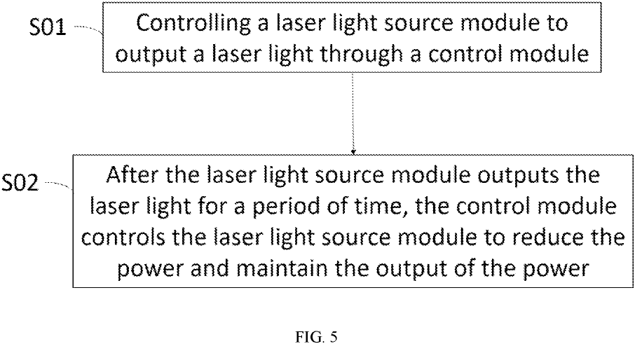

FIG. 5 is a flowchart of the laser control method of the present invention, comprising the following steps:

Step S01: Controlling the power supply device of the laser light source module to output the initial voltage through the control module, so that the laser element of the laser light source module outputs laser light with initial power.

Step S02: After the laser element outputs the laser light with the initial voltage for a period of time, the control module is used to reduce the initial voltage to the operating voltage, thereby reducing the initial power to the operating power and maintaining the output of the laser with the operating power until the laser is turned off.

In one embodiment, the operator can set the required laser processing programs for different types of processing objects to the control module and store them in advance through the above-mentioned operation interface, and only needs to select the corresponding program when getting on the machine.

The present invention provides a laser control system and method for self-modulating power. By modulating the voltage supplied to the laser, the electrical power loss can be reduced and the energy saving effect can be achieved.

What is claimed is:

1. A laser control system with self-modulating power, comprising:
a control module; and
a laser light source module connected to the control module for modulating laser power;
when the laser light source module outputs the laser light with an initial power for a period of time, the control module controls the laser light source module to reduce the initial power to the operation power and maintains the output of the laser light with the operation power.

2. The laser control system according to claim 1, wherein the laser light source module comprises:
a laser element for outputting the laser light with the initial power or the operation power; and
a power supply device connected between the control module and the laser element for providing an initial voltage or an operating voltage to the laser element;
when the power supply device provides the initial voltage for the period of time, the control module controls the power supply device to reduce the initial voltage to the operating voltage and maintains supplying the operating voltage to the laser element.

3. The laser control system according to claim 1, wherein the period of time is between 10 and 30 µs.

4. The laser control system according to claim 2, wherein the laser element is a semiconductor laser, an optical fiber laser, a carbon dioxide laser, a solid-state laser, a liquid laser, a gas laser, a YAG laser or a combination thereof.

5. A laser control method for self-modulating power, comprising:
controlling a laser light source module to output a laser light with an initial power through a control module; and
when the laser light source module outputs the laser light with the initial power for a period of time, the control module controls the laser light source module to reduce the initial power to an operating power and maintain the output of the laser light with the operation power.

6. The laser control method according to claim 5, further comprising a laser processing program is preset in the control module.

7. The laser control method according to claim 5, wherein the period of time is between 10 and 30 µs.
